(19) United States
(12) Patent Application Publication
(10) Pub. No.: US 2024/0072027 A1
(43) Pub. Date: Feb. 29, 2024

(54) METHOD OF FABRICATING DISPLAY PANEL

(71) Applicant: Samsung Display Co., LTD., Yongin-si (KR)

(72) Inventors: Jeong Won HAN, Yongin-si (KR); Won Hee OH, Yongin-si (KR)

(21) Appl. No.: 18/453,190

(22) Filed: Aug. 21, 2023

(30) Foreign Application Priority Data
Aug. 31, 2022 (KR) 10-2022-0110033

(51) Int. Cl. H01L 25/16; H01L 21/67; H01L 21/683; H01L 23/00

(52) U.S. Cl. CPC H01L 25/167; H01L 21/67144; H01L 21/6835; H01L 24/80; H01L 24/81; H01L 24/83; H01L 24/95; H01L 24/05; H01L 24/08; H01L 2221/68381; H01L 2224/05073; H01L 2224/05124; H01L 2224/05138; H01L 2224/05144; H01L 2224/05147; H01L 2224/05155; H01L 2224/05166; H01L 2224/05171; H01L 2224/0518; H01L 2224/05573; H01L 2224/05609; H01L 2224/05611; H01L 2224/05624; H01L 2224/05639; H01L 2224/05644; H01L 2224/05655; H01L 2224/05664; H01L 2224/05686; H01L 2224/05693; H01L 2224/08145; H01L 2224/80006; H01L 2224/80024; H01L 2224/80224; H01L 2224/80805; H01L 2224/81005; H01L 2224/81815; H01L 2224/83005; H01L 2224/95001; H01L 2924/01006; H01L 2924/0106; H01L 2924/0549; H01L 2924/12041

(57) ABSTRACT

The present disclosure may provide a method of fabricating a display panel, the method includes picking up, by a transfer head, a transfer member located on a support member, detaching a light-emitting element from a donor substrate by attaching the transfer member picked up by the transfer head to the light-emitting element on the donor substrate to lift the light-emitting element, aligning, by the transfer head, the light-emitting element attached to the transfer member on a circuit board, and detaching the transfer member from the transfer head, bonding the light-emitting element attached to the transfer member onto the circuit board and separating, by the transfer head, the transfer member from the light-emitting element bonded to the circuit board to remove the transfer member.

### CROSS-REFERENCE TO RELATED APPLICATION

This application claims priority to and the benefit of Korean Patent Application No. 10-2022-0110033 filed on Aug. 31, 2022, in the Korean Intellectual Property Office, the entire disclosure of which is incorporated by reference herein.

### BACKGROUND

### 1. Field

The present disclosure relates to a method of fabricating a display panel.

### 2. Description of the Related Art

Display devices become more and more important as multimedia technology evolves. Accordingly, a variety of types of display devices such as organic light-emitting diode (OLED) display devices and liquid-crystal display (LCD) devices are currently used.

Display devices include a display panel such as a light-emitting display panel and a liquid-crystal display panel for displaying images. Among them, light-emitting display panel may include light-emitting diodes (LEDs). Light-emitting diodes may include an organic light-emitting diode (OLED) using an organic material as a luminescent material, an inorganic light-emitting diode using an inorganic material as a luminescent material, etc.

To fabricate a display panel using inorganic light-emitting diodes as light-emitting diodes, apparatuses for disposing micro LEDs on the substrate of the display panel should be developed.

### SUMMARY

Aspects and features of embodiments of the present disclosure provide an apparatus for fabricating a display panel that can eliminate the issue of contamination on a transfer member by way of transferring light-emitting elements on a donor substrate onto a circuit board using a disposable transfer member.

Aspects and features of embodiments of the present disclosure also provide an apparatus for fabricating a display panel that can prevent contamination of a laser-transfer member by way of avoiding a flux from being in direct contact with the laser-transmitting member by removing the transfer member after the bonding process between the light-emitting elements and the circuit board.

However, aspects and features of embodiments of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments, a method of fabricating a display panel includes picking up, by a transfer head, a transfer member located on a support member, detaching a light-emitting element from a donor substrate by attaching the transfer member picked up by the transfer head to the light-emitting element on the donor substrate to lift the light-emitting element, aligning, by the transfer head, the light-emitting element attached to the transfer member on a circuit board, and detaching the transfer member from the transfer head, bonding the light-emitting element attached to the transfer member onto the circuit board; and separating, by the transfer head, the transfer member from the light-emitting element bonded to the circuit board to remove the transfer member.

The transfer member includes a base layer and a stamp layer on a surface of the base layer, and wherein the stamp layer includes a material that is adhesive or detachable.

The protective film is located between the support member and the transfer member, and wherein the protective film is attached to a surface of the stamp layer and the base layer is attached to an opposite surface of the stamp layer.

The picking up the transfer member includes picking up, by the transfer head, the transfer member by adsorbing the base layer, and holding the transfer member to separate the protective film from the transfer member.

The circuit board includes a flux applied onto one surface.

The method of fabricating a display panel further includes after the separating the transfer member from the light-emitting element bonded to the circuit board to remove the transfer member, removing the flux from the circuit board by a flux cleaner.

The bonding the light-emitting element onto the circuit board includes at least one of: an eutectic bonding by irradiating laser onto a bonding electrode at one end of the light-emitting element to melt the bonding electrode and bond the light-emitting element to the circuit board; a soldering bonding by melting and bonding a solder ball between the light-emitting element and the circuit board; and an anisotropic conductive film (ACF) bonding by heating and bonding an anisotropic conductive film between the light-emitting element and the circuit board.

The support member supports a plurality of transfer members, and wherein each of the plurality of transfer members has a same transfer unit size as a transfer area on the circuit board that is transferred at one time.

The light-emitting element includes an n-type semiconductor, an active layer, a p-type semiconductor, a first contact electrode, and a second contact electrode.

According to one or more embodiments, a method of fabricating a display panel, includes picking up, by a first head, a mother substrate for transfer members that is on a support member and has a protective film attached to the mother substrate, holding, by the first head, the mother substrate to separate the protective film from the mother substrate, attaching, by the first head, the mother substrate onto light-emitting elements arranged and aligned on a donor substrate, and detaching the mother substrate from the first head, cutting the mother substrate into a transfer unit size on the donor substrate to prepare the transfer members, arranging, by a second head, the transfer member having the light-emitting elements attached thereto on a circuit board, and detaching the transfer member from the second head, bonding the light-emitting elements attached to the transfer member onto the circuit board and separating, by the second head, the transfer member from the light-emitting elements bonded to the circuit board to remove the transfer member.

The mother substrate includes a base layer and a stamp layer on a surface of the base layer, and wherein the stamp layer includes a material that is adhesive or detachable.

The protective film is attached to one surface of the stamp layer and the base layer is attached to an opposite surface.

The circuit board includes a flux applied onto one surface.

The method of fabricating a display panel, includes after the separating the transfer members from the light-emitting elements bonded to the circuit board to remove the transfer members, removing the flux from the circuit board by a flux cleaner.

A size of the second head is smaller than or equal to the transfer unit size and smaller than a size of the first head.

The bonding the light-emitting elements onto the circuit board includes at least one of: an eutectic bonding by irradiating laser onto a bonding electrode at one end of the light-emitting elements to melt the bonding electrode and bond the light emitting elements to the circuit board; a soldering bonding by melting and bonding a solder ball between the light-emitting elements and the circuit board; and an anisotropic conductive film (ACF) bonding by heating and bonding an anisotropic conductive film between the light-emitting elements and the circuit board.

According to one or more embodiments, a method of fabricating a display panel, includes placing a mother substrate for transfer members having a protective film on a support member, cutting the mother substrate having the protective film into a transfer unit size on the support member to prepare the transfer members, picking up the transfer members using a reversing member or a robot and reversing the transfer members vertically and horizontally, picking up, by a transfer head, a transfer member of the transfer members to hold the transfer member to separate the protective film from the transfer member, attaching, by the transfer head, light-emitting elements on a donor substrate to the picked up transfer member and detaching the light-emitting elements from the donor substrate, aligning, by the transfer head, the transfer member having the light-emitting elements attached thereto on a circuit board, and detaching the transfer member from the transfer head, bonding the light-emitting elements attached to the transfer member on the circuit board and separating, by the transfer head, the transfer member from the light-emitting elements on the circuit board to remove the transfer member.

The mother substrate includes a base layer and a stamp layer on a surface of the base layer, and wherein the stamp layer includes a material that is adhesive or detachable.

The placing the mother substrate includes disposing the mother substrate such that the base layer, the stamp layer, and the protective film are arranged in order on the support member.

The disposing the mother substrate includes disposing the mother substrate of a roll-to-roll type or a sheet type.

The circuit board includes a flux applied onto one surface.

The method of fabricating a display panel, includes after the separating the transfer members from the light-emitting element on the circuit board to remove the transfer member, removing the flux from the circuit board by a flux cleaner.

According to one or more embodiments of the present disclosure, it is possible to address the issue of defective transfer due to contamination on a transfer member by way of transferring light-emitting elements on a donor substrate onto a circuit board using a disposable transfer member.

In addition, it is possible to prevent contamination of a laser-transmitting member by way of avoiding a flux from being in direct contact with the laser-transmitting member since the transfer member is removed after the bonding process between the light-emitting elements and a circuit board.

However, the effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings.

FIG. 1 is a view showing a layout of a display device according to one or more embodiments of the present disclosure.

FIG. 2 is a view showing an example of a pixel of FIG. 1.

FIG. 3 is a view showing another example of a pixel of FIG. 1.

FIG. 4 is a cross-sectional view showing an example of the display panel taken along the line A-A′ of FIG. 2.

FIG. 5 is a flowchart for illustrating a method of fabricating a display panel according to one or more embodiments of the present disclosure.

FIG. 6 is a view for illustrating picking up a transfer member disposed on a support member according to one or more embodiments.

FIG. 7 is a cross-sectional view showing a transfer member having a protective film attached thereto according to one or more embodiments of the present disclosure.

FIG. 8 is a cross-sectional view showing a transfer member after a protective film has been detached from it.

FIG. 9 is a view for illustrating picking up light-emitting elements attached on a donor substrate.

FIG. 10 is a view for illustrating a method of transferring light-emitting elements onto a circuit board.

FIG. 11 is a view for illustrating a method of bonding light-emitting elements onto a circuit board.

FIG. 12 is a view for illustrating a method of separating a transfer member on a circuit board.

FIG. 13 is a view for illustrating a method of cleaning a flux from a circuit board.

FIG. 14 is an enlarged view of an area A of FIG. 13.

FIG. 15 is a flowchart for illustrating a method of fabricating a display panel according to one or more embodiments of the present disclosure.

FIG. 16 is a cross-sectional view of a mother substrate for transfer members disposed on a support member.

FIG. 17 is a view for illustrating picking up the mother substrate.

FIG. 18 is a cross-sectional view showing the mother substrate after the protective film has been detached from it.

FIG. 19 is a view for illustrating a process of disposing a mother substrate on light-emitting elements.

FIG. 20 is a view showing a process of cutting the mother substrate into a transfer unit size.

FIG. 21 is a view for illustrating picking up light-emitting elements attached on a donor substrate.

FIGS. 22 to 23 are views for illustrating a method of transferring light-emitting elements onto a circuit board according to one or more embodiments.

FIG. 24 is a view for illustrating a method of transferring light-emitting elements onto a circuit board according to one or more embodiments.

FIG. 25 is a view for illustrating a method of bonding light-emitting elements onto a circuit board.

FIG. 26 is a view for illustrating a method of separating a transfer member on a circuit board.

FIG. 27 is a view for illustrating a method of cleaning a flux from a circuit board.

FIG. 28 is a flowchart for illustrating a method of fabricating a display panel according to one or more embodiments of the present disclosure.

FIG. 29 is a perspective view for illustrating a mother substrate for transfer members of a roll-to-roll type.

FIG. 30 is a perspective view for illustrating a mother substrate for transfer members of a sheet type.

FIG. 31 is a cross-sectional view of a transfer member disposed upside down on a support member.

FIG. 32 is a view showing a process of cutting the mother substrate into a transfer unit size.

FIGS. 33 and 34 are views for illustrating reversing transfer members by a reversing member.

FIG. 35 is a view for illustrating picking up a transfer member.

FIGS. 36 and 37 are views for illustrating reversing transfer members by a reversing member.

FIG. 38 is a view illustrating a virtual reality device including a display device according to one or more embodiments.

FIG. 39 is a view illustrating a smart device including a display device according to one or more embodiments.

FIG. 40 is a view illustrating a vehicle dashboard and a center fascia including display devices according to one or more embodiments.

FIG. 41 is a view illustrating a transparent display device including a display device according to one or more embodiments.

### DETAILED DESCRIPTION

Aspects and features of the present disclosure and methods to achieve them will become apparent from the descriptions of embodiments hereinbelow with reference to the accompanying drawings. However, the present disclosure is not limited to embodiments disclosed herein but may be implemented in various different ways. The embodiments are provided for making the present disclosure thorough and for fully conveying the spirit and scope of the present disclosure to those skilled in the art. It is to be noted that the scope of the present disclosure is defined by the claims and their equivalents.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Hereinafter, embodiments of the present disclosure will be described with reference to the accompanying drawings.

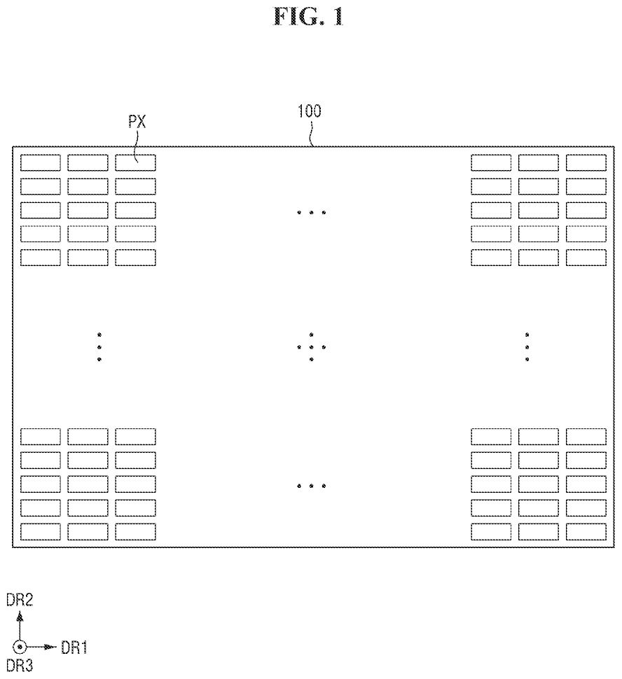

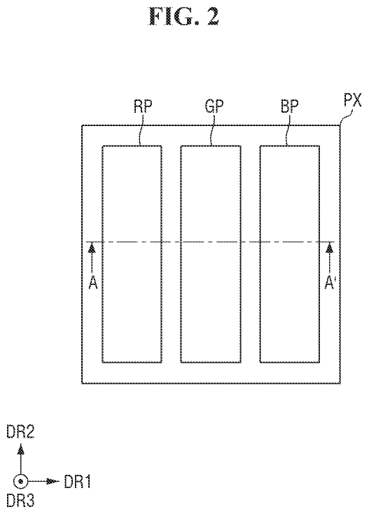

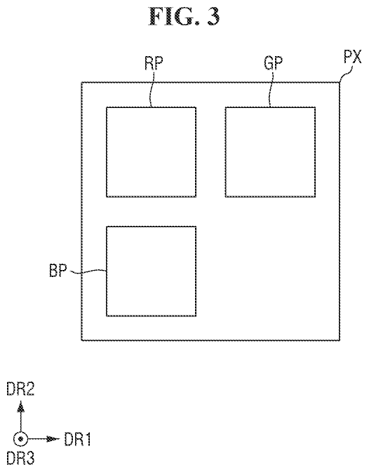

FIG. 1 is a view showing a layout of a display device according to one or more embodiments of the present disclosure. FIG. 2 is a view showing an example of a pixel of FIG. 1. FIG. 3 is a view showing another example of a pixel of FIG. 1.

Referring to FIGS. 1 to 3, a display device including a display panel 100 is for displaying moving images or still images. The display device may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things (IoT) device.

The display panel 100 may be formed in a rectangular plane having longer sides in the first direction DR1 and shorter sides in the second direction DR2 intersecting (or crossing) the first direction DR1. Each of the corners where the longer side in the first direction DR1 meets the shorter side in the second direction DR2 may be rounded with a suitable curvature (e.g., a predetermined curvature) or may be a right angle. The shape of the display panel 100 when viewed from the top is not limited to a quadrangular shape, but may be formed in a different polygonal shape, a circular shape, or an elliptical shape. The display panel 100 may be formed flat, but is not limited thereto. For example, the display panel 100 may be formed at left and right ends, and may include a curved portion having a constant curvature or a varying curvature. In addition, the display panel 100 may be flexible so that it can be curved, bent, folded, and/or rolled.

The display panel 100 may further include pixels PX for displaying images; scan lines extended in the first direction DR1; and data lines extended in the second direction DR2. The pixels PX may be arranged in a matrix along the first direction DR1 and the second direction DR2. For example, the pixels PX may be arranged along rows and columns of a matrix along the first direction DR1 and the second direction DR2.

Each of the pixels PX may include a plurality of sub-pixels RP, GP, and BP as shown in FIGS. 2 and 3. Although each of the pixels PX includes three sub-pixels RP, GP, and BP, that is, a first sub-pixel RP, a second sub-pixel GP, and a third sub-pixel BP in the examples shown in FIGS. 2 and 3, the embodiments of the present disclosure are not limited thereto.

The first sub-pixel RP, the second sub-pixel GP, and the third sub-pixel BP may be connected to one of data line lines, and at least one of the scan lines.

Each of the first sub-pixel RP, the second sub-pixel GP, and the third sub-pixel BP may have a rectangular, square, or diamond shape when viewed from the top. For example, each of the first sub-pixel RP, the second sub-pixel GP, and the third sub-pixel BP may have a rectangular shape having shorter sides in the first direction DR1 and longer sides in the second direction DR2 when viewed from the top as shown in FIG. 2. Alternatively, each of the first sub-pixel RP, the second sub-pixel GP, and the third sub-pixel BP may have a square shape having sides of equal length in the first direction DR1 and the second direction DR2 as shown in FIG. 3 or a diamond shape when viewed from the top.

As shown in FIG. 2, the first sub-pixel RP, the second sub-pixel GP, and the third sub-pixel BP may be arranged along the first direction DR1. Alternatively, one of the second sub-pixel GP and the third sub-pixel BP, and the first sub-pixel RP may be arranged along the first direction DR1, and the other one and the first sub-pixel RP may be arranged along the second direction DR2. For example, as shown in FIG. 3, the first sub-pixel RP and the second sub-pixel GP may be arranged along the first direction DR1, and the first sub-pixel RP and the third sub-pixel BP may be arranged along the second direction DR2.

Alternatively, one of the first sub-pixel RP and the third sub-pixel BP, and the second sub-pixel GP may be arranged along the first direction DR1, and the other one and the second sub-pixel GP may be arranged along the second direction DR2. Alternatively, one of the first sub-pixel RP and the second sub-pixel GP and the third sub-pixel BP may be arranged along the first direction DR1, and the other one and the third sub-pixel BP may be arranged along the second direction DR2.

The first sub-pixel RP may include a first light-emitting element emitting a first light, the second sub-pixel GP may include a second light-emitting element emitting a second light, and the third sub-pixel BP may include a third light-emitting element emitting a third light. The first light may be light of a red wavelength range, the second light may be light of a green wavelength range, and the third light may be light of a blue wavelength range. The red wavelength range may range approximately from 600 nm to 750 nm, the green wavelength range may range approximately from 480 nm to 560 nm, and the blue wavelength range may range approximately from 370 nm to 460 nm. It should be understood, however, that one or more embodiments of the present disclosure are not limited thereto.

Each of the first sub-pixel RP, the second sub-pixel GP, and the third sub-pixel BP may include an inorganic light-emitting element having an inorganic semiconductor as a light-emitting element that emits light. For example, the inorganic light-emitting element may be, but is not limited to, a flip-chip micro light-emitting diode (LED).

As shown in FIGS. 2 and 3, the first sub-pixel RP, the second sub-pixel GP, and the third sub-pixel BP may have the same area when viewed from the top. It is, however, to be understood that embodiments of the present disclosure are not limited thereto. The area of at least one of the first sub-pixel RP, the second sub-pixel GP, and the third sub-pixel BP may be different from the area of others. Alternatively, the areas of two of the first sub-pixel RP, the second sub-pixel GP, and the third sub-pixel BP may be equal while the area of the other may be different from it. Alternatively, the first sub-pixels RP, the second sub-pixels GP, and the third sub-pixels BP may have different areas.

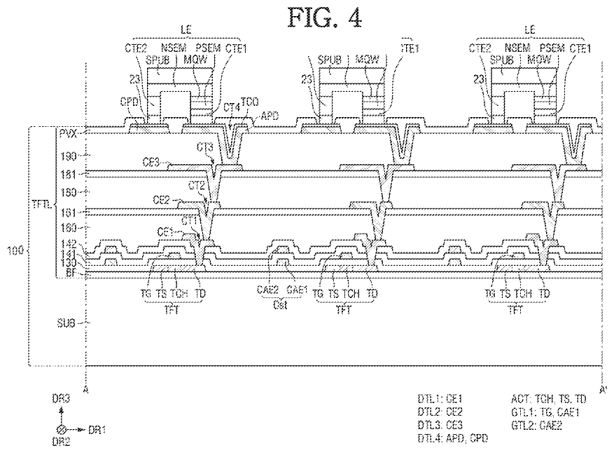

FIG. 4 is a cross-sectional view showing an example of the display panel taken along the line A-A′ of FIG. 2.

Referring to FIG. 4, the display panel 100 may include a thin-film transistor layer TFTL disposed on a substrate SUB, and light-emitting elements LE. The thin-film transistor layer TFTL may be a layer in which thin-film transistors TFTs are formed.

The thin-film transistor layer TFTL includes an active layer ACT, a first gate layer GTL1, a second gate layer GTL2, a first data metal layer DTL1, a second data metal layer DTL2, a third data metal layer DTL3, and a fourth data metal layer DTL4. In addition, the thin-film transistor layer TFTL includes a buffer layer BF, a gate insulator 130, a first interlayer dielectric layer 141, a second interlayer dielectric layer 142, a first planarization layer 160, a first insulating layer 161, a second planarization layer 180, a second insulating layer 181, a third planarization layer 190, and a passivation layer PVX.

The substrate SUB may be a base substrate or a base member for supporting the display device. The substrate SUB may be, but is not limited to, a rigid substrate made of glass. The substrate SUB may be a flexible substrate that can be bent, folded, and/or rolled. In this instance, the substrate SUB may include an insulating material such as a polymer resin including polyimide (PI).

The buffer layer BF may be disposed on a surface of the substrate SUB. The buffer layer BF may prevent the permeation of air or moisture. The buffer layer BF may be formed of a plurality of inorganic layers stacked on one another alternately. For example, the buffer layer BF may be made up of multiple layers in which one or more inorganic layers selected from the group of a silicon nitride layer, a silicon oxynitride layer, a silicon oxide layer, a titanium oxide layer, and/or an aluminum oxide layer are alternately stacked on one another. The buffer layer BF may be eliminated.

The active layer ACT may be disposed on the buffer layer BF. The active layer ACT may include silicon semiconductor such as polycrystalline silicon, monocrystalline silicon, low-temperature polycrystalline silicon, and/or amorphous silicon, or may include oxide semiconductor.

The active layer ACT may include a channel TCH, a first electrode TS, and a second electrode TD of a thin-film transistor TFT. The channel TCH of the thin-film transistor TFT may be a region overlapping the gate electrode TG of the thin-film transistor TFT in the third direction DR3, which is the thickness direction of the substrate SUB. The first electrode TS of the thin-film transistor TFT may be disposed on one side of the channel TCH, and the second electrode TD may be disposed on the opposite side of the channel TCH. The first electrode TS and the second electrode TD of the thin-film transistor TFT may be regions that do not overlap with the gate electrode TG in the third direction DR3. The first electrode TS and the second electrode TD of the thin-film transistor TFT may be regions having conductivity by doping ions in a silicon semiconductor or an oxide semiconductor.

The gate insulator 130 may be disposed on the active layer ACT and the buffer layer BF. The gate insulator 130 may be formed of an inorganic layer, for example, a silicon nitride layer, a silicon oxynitride layer, a silicon oxide layer, a titanium oxide layer, and/or an aluminum oxide layer.

The first gate layer GTL1 may be disposed on the gate insulator 130. The first gate layer GTL1 may include the gate electrode TG of the thin-film transistor TFT and a first capacitor electrode CAE1. The first gate layer GTL1 may include a single layer or multiple layers of one or more selected from the group of molybdenum (Mo), aluminum (Al), chromium (Cr), gold (Au), titanium (Ti), nickel (Ni), neodymium (Nd), and/or copper (Cu), and/or an alloy thereof.

The first interlayer dielectric layer 141 may be disposed over the first gate layer GTL1 and the gate insulator 130. The first interlayer dielectric layer 141 may be formed of an inorganic layer, for example, a silicon nitride layer, a silicon oxynitride layer, a silicon oxide layer, a titanium oxide layer, and/or an aluminum oxide layer.

The second gate layer GTL2 may be disposed on the first interlayer dielectric layer 141. The second gate layer GTL2 may include a second capacitor electrode CAE2. The second gate layer GTL2 may include a single layer or multiple layers of one or more selected from the group of molybdenum (Mo), aluminum (Al), chromium (Cr), gold (Au), titanium (Ti), nickel (Ni), neodymium (Nd), and/or copper (Cu), and/or an alloy thereof.

The second interlayer dielectric layer 142 may be disposed over the second gate layer GTL2 and the first interlayer dielectric layer 141. The second interlayer dielectric layer 142 may be formed of an inorganic layer, for example, a silicon nitride layer, a silicon oxynitride layer, a silicon oxide layer, a titanium oxide layer, and/or an aluminum oxide layer.

In one or more embodiments, the first data metal layer DTL1 including a first connection electrode CE1, a first sub pad, and a data line may be disposed on the second interlayer dielectric layer 142. The data line may be formed integrally with the first sub pad, but the embodiments of the present disclosure are not limited thereto. The first data metal layer DTL1 may include a single layer or multiple layers of one or more selected from the group of molybdenum (Mo), aluminum (Al), chromium (Cr), gold (Au), titanium (Ti), nickel (Ni), neodymium (Nd), and/or copper (Cu), and/or an alloy thereof.

The first connection electrode CE1 may be connected to the first electrode TS or the second electrode TD of the thin-film transistor TFT through a first contact hole CT1 penetrating the gate insulator 130, the first interlayer dielectric layer 141, and the second interlayer dielectric layer 142.

The first planarization layer 160 may be disposed on the first data metal layer DTL1 and the second interlayer dielectric layer 142 to provide a flat surface over the level differences of the active layer ACT, the first gate layer GTL1, the second gate layer GTL2, and the first data metal layer DTL1. The first planarization layer 160 may be formed of an organic layer such as an acryl resin, an epoxy resin, a phenolic resin, a polyamide resin, and/or a polyimide resin.

A first insulating layer 161 may be on the first planarization layer 160. In one or more embodiments, a second data metal layer DTL2 may be disposed on the first planarization layer 160 and the first insulating layer 161. The second data metal layer DTL2 may include a second connection electrode CE2 and a second sub pad. The second connection electrode CE2 may be connected to the first connection electrode CE1 through a second contact hole CT2 penetrating the first insulating layer 161 and the first planarization layer 160. The second data metal layer DTL2 may include a single layer or multiple layers of one or more selected from the group of molybdenum (Mo), aluminum (Al), chromium (Cr), gold (Au), titanium (Ti), nickel (Ni), neodymium (Nd), and/or copper (Cu), and/or an alloy thereof.

The second planarization layer 180 may be disposed on the second data metal layer DTL2 and the first insulating layer 161. The second planarization layer 180 may be formed as an organic layer including an acryl resin, an epoxy resin, a phenolic resin, a polyamide resin, and/or a polyimide resin.

A second insulating layer 181 may be on the second planarization layer 180. The third data metal layer DTL3 may be disposed on the second planarization layer 180 and the second insulating layer 181. In one or more embodiments, the third data metal layer DTL3 may include a third connection electrode CE3 and a third sub pad.

The third connection electrode CE3 may be connected to the second connection electrode CE2 through a third contact hole CT3 penetrating the second insulating layer 181 and the second planarization layer 180. The third data metal layer DTL3 may include a single layer or multiple layers of one or more selected from the group of molybdenum (Mo), aluminum (Al), chromium (Cr), gold (Au), titanium (Ti), nickel (Ni), neodymium (Nd), and/or copper (Cu), and/or an alloy thereof.

A third planarization layer 190 may be disposed on the third data metal layer DTL3 and the second insulating layer 181. The third planarization layer 190 may be formed as an organic layer including an acryl resin, an epoxy resin, a phenolic resin, a polyamide resin, and/or a polyimide resin.

The fourth data metal layer DTL4 may be disposed on the third planarization layer 190 and the second insulating layer 181. The fourth data metal layer DTL4 may include an anode pad electrode APD, a cathode pad electrode CPD, and a fourth sub pad. The anode pad electrode APD may be connected to the third connection electrode CE3 through a fourth contact hole CT4 penetrating the third planarization layer 190. In one pr more other embodiments, a third insulating layer may be disposed on the third planarization layer 190. The cathode pad electrode CPD may receive a first supply voltage, which is a low-level voltage. The fourth data metal layer DTL4 may include a single layer or multiple layers of one or more selected from the group of molybdenum (Mo), aluminum (Al), chromium (Cr), gold (Au), titanium (Ti), nickel (Ni), neodymium (Nd), and/or copper (Cu), and/or an alloy thereof.

On the anode pad electrode APD and the cathode pad electrode CPD, a transparent conductive layer TCO for increasing adhesion with the first and second contact electrodes CTE1 and CTE2 of the light-emitting element LE and a fifth sub pad may be disposed. The transparent conductive layer TCO and the fifth sub pad may be made of a transparent conductive oxide such as indium tin oxide (ITO) and/or indium zinc oxide (IZO).

A passivation layer PVX may be disposed on the anode pad electrode APD, the cathode pad electrode CPD, and the first pad. The passivation layer PVX may be disposed to cover edges of the anode pad electrode APD, the cathode pad electrode CPD, and the first pad. The passivation layer PVX may be formed of an inorganic layer, for example, a silicon nitride layer, a silicon oxynitride layer, a silicon oxide layer, a titanium oxide layer, and/or an aluminum oxide layer.

A flip-chip micro LED in which the first contact electrode CTE1 and the second contact electrode CTE2 face the anode pad electrode APD and the cathode pad electrode CPD, respectively, is employed as an example of the light-emitting element LE. It should be understood, however, that the present disclosure is not limited thereto. The light-emitting element LE may be an inorganic light-emitting element made of an inorganic material such as GaN. The lengths of the light-emitting element LE in the first direction DR1, the second direction DR2, and the third direction DR3 may range from several to hundreds μm. For example, the lengths of the light-emitting element LE in the first direction DR1, the second direction DR2, and the third direction DR3 may be equal to or less than 100 μm.

The light-emitting elements LE may be formed by being grown on a semiconductor substrate such as a silicon wafer. Each of the light-emitting elements LE may be transferred directly from the silicon wafer onto the anode pad electrode APD and the cathode pad electrode CPD of the substrate SUB. In this instance, the first contact electrode CTE1 and the anode pad electrode APD may be bonded to each other via a bonding process. In addition, the second contact electrode CTE2 and the cathode pad electrode CPD may be bonded to each other via a bonding process. The first contact electrode CTE1 and the anode pad electrode APD may be electrically connected to each other through a bonding electrode 23. In addition, the second contact electrode CTE2 and the cathode pad electrode CPD may be electrically connected to each other through the bonding electrode 23.

For example, the bonding electrode 23 may be disposed on one surface of the light-emitting element LE. The bonding electrodes 23 may be melted by laser for bonding. Herein, the bonding by pressing and melting refers to that the bonding electrodes 23 are heated and melted so that the light-emitting elements LE are melted and mixed with the anode pad electrode APD and the cathode pad electrode CPD, and they are cooled and solidified after the laser supply is terminated. Because the light-emitting elements LE and the anode pad electrode APD and the cathode pad electrode CPD maintain conductivity even though they are cooled and solidified after they have been melted and mixed, the anode pad electrode APD and the cathode pad electrode CPD, and the light-emitting elements LE can be electrically and physically connected with each other. Accordingly, the bonding electrode 23 may be disposed on the first contact electrode CTE1 and the second contact electrode CTE2 of the light-emitting element LE.

The bonding electrode 23 may include, for example, Au, AuSn, PdIn, InSn, NiSn, Au—Au, AgIn, AgSn, Al, Ag, and/or carbon nanotube (CNT). These may be used alone or in combination of two or more. Depending on the type of the bonding electrode 23, the bonding electrode 23 may be formed on the pad electrode by deposition or various other methods such as screen printing.

Alternatively, each of the light-emitting elements LE may be transferred onto the anode pad electrode APD and the cathode pad electrode CPD of the substrate SUB by using a transfer member. A description thereof will be given below with reference to FIGS. 5 to 37.

Each of the light-emitting elements LE may be a light-emitting structure that includes a base substrate SPUB, an n-type semiconductor NSEM, an active layer MQW, a p-type semiconductor PSEM, a first contact electrode CTE1, and a second contact electrode CTE2.

The base substrate SPUB may be, but is not limited to, a sapphire substrate.

The n-type semiconductor NSEM may be disposed on one surface of the base substrate SPUB. For example, the n-type semiconductor NSEM may be disposed on the lower surface of the base substrate SPUB. The n-type semiconductor NSEM may be made of GaN doped with an n-type conductive dopant such as Si, Ge, and/or Sn.

The active layer MQW may be disposed on a part of one surface of the n-type semiconductor NSEM. The active layer MQW may include a material having a single or multiple quantum well structure. When the active layer MQW includes a material having the multiple quantum well structure, well layers and barrier layers may be alternately stacked on one another in the structure. The well layers may be made of InGaN, and the barrier layers may be made of GaN and/or AlGaN, but the present disclosure is not limited thereto. Alternatively, the active layer MQW may have a structure in which a semiconductor material having a large energy band gap and a semiconductor material having a small energy band gap are alternately stacked on one another, and may include other Group III to Group V semiconductor materials depending on the wavelength range of the emitted light.

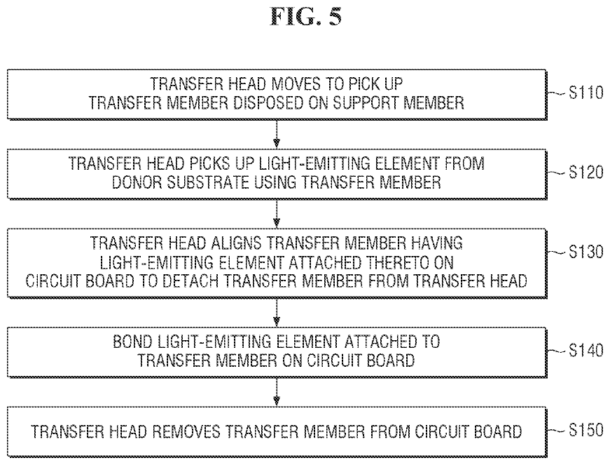

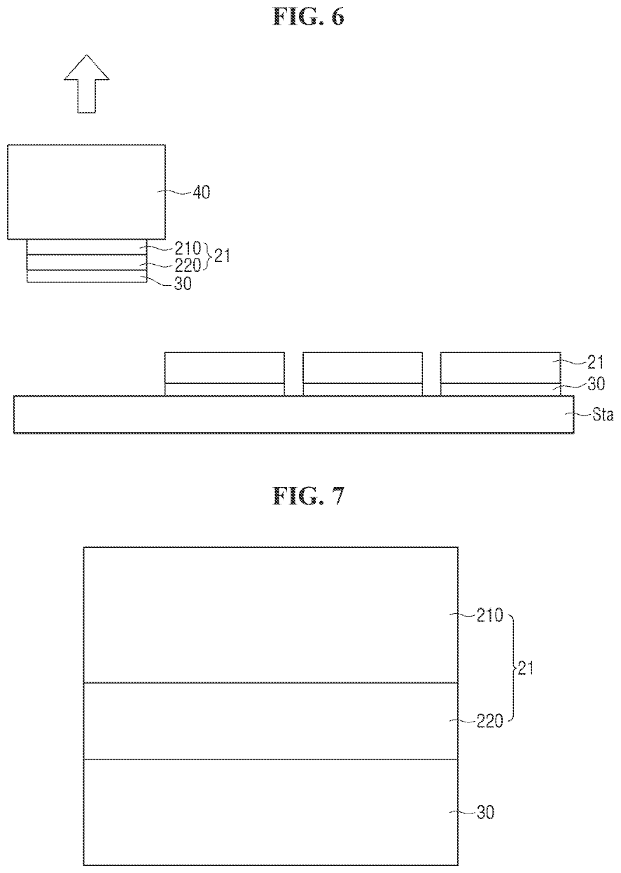

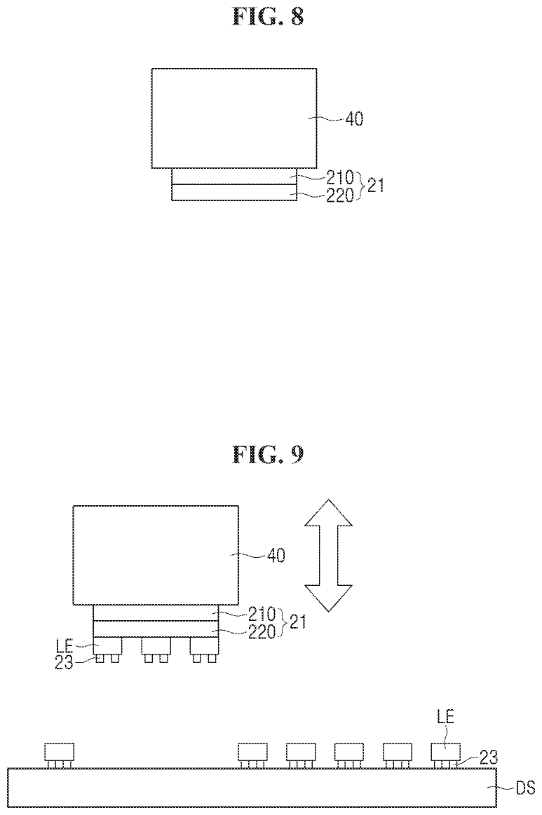

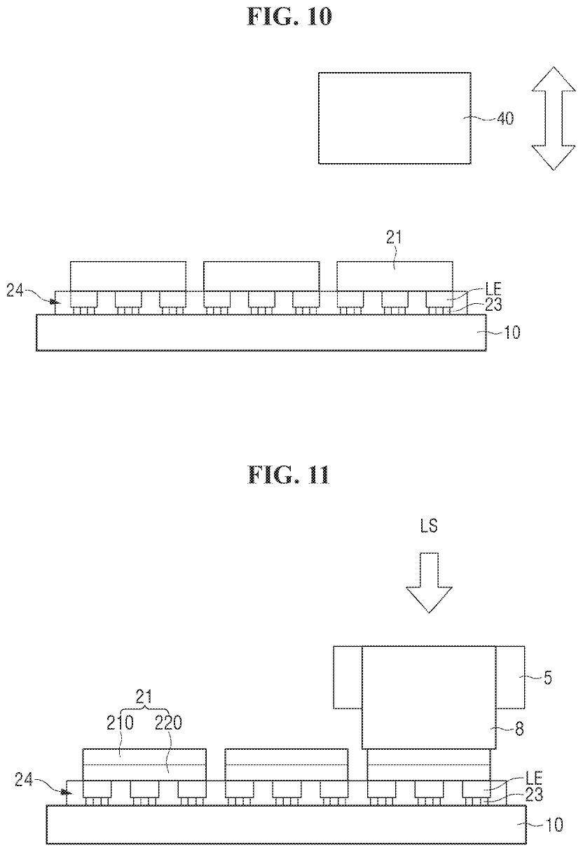

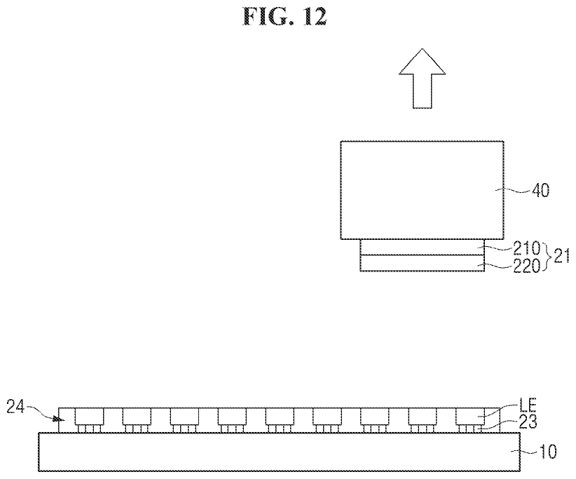

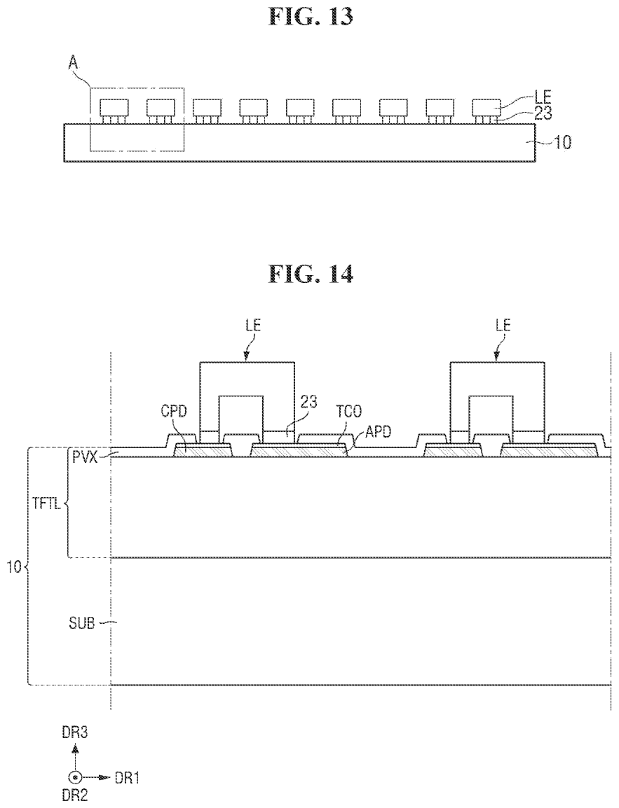

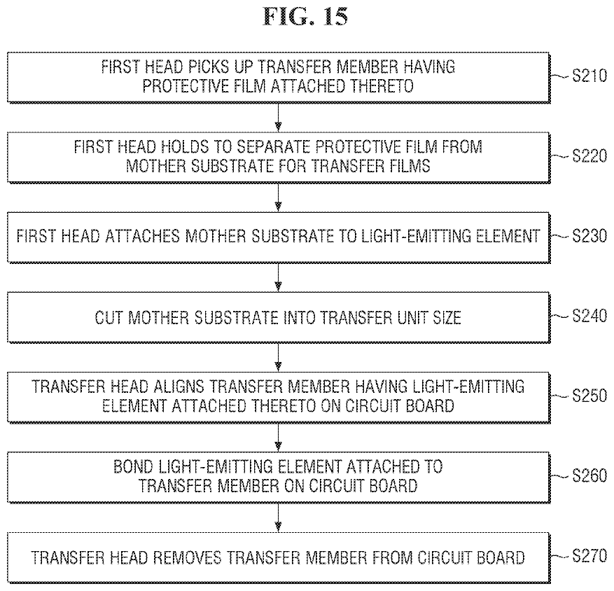

FIG. 5 is a flowchart for illustrating a method of fabricating a display panel according to one or more embodiments of the present disclosure. FIG. 6 is a view for illustrating picking up a transfer member disposed on a support member according to one or more embodiments. FIG. 7 is a cross-sectional view showing a transfer member having a protective film attached thereto according to one or more embodiments of the present disclosure. FIG. 8 is a cross-sectional view showing a transfer member after a protective film has been detached from it. FIG. 9 is a view for illustrating picking up light-emitting elements attached on a donor substrate. FIG. 10 is a view for illustrating a method of transferring light-emitting elements onto a circuit board. FIG. 11 is a view for illustrating a method of bonding light-emitting elements onto a circuit board. FIG. 12 is a view for illustrating a method of separating a transfer member on a circuit board. FIG. 13 is a view for illustrating a method of cleaning a flux from a circuit board. FIG. 14 is an enlarged view of an area A of FIG. 13.

A method of fabricating a display panel using a transfer member according to one or more embodiments will be described with reference to FIGS. 5 to 14.

According to one or more embodiments of the present disclosure, light-emitting elements LE may be transferred from a donor substrate DS (e.g., see FIG. 9) to a circuit board 10 (e.g., see FIG. 10) by a transfer member 21.

Referring initially to FIG. 5, a transfer head 40 moves to pick up a transfer member 21 placed on a support member Sta (step S110).

More specifically, as shown in FIG. 6, a transfer head 40 may pick up one of a plurality of transfer members 21 arranged on a support member Sta.

The support member Sta serves to support the plurality of transfer members 21. The plurality of transfer members 21 may be aligned and arranged on the support member Sta.

For example, the transfer head 40 may move above the support member Sta and adsorb the upper surface of a transfer member 21 arranged on the support member Sta. For another example, the support member Sta may move toward the transfer head 40 and the upper surface of a transfer member 21 arranged on the support member Sta may be adsorbed. To this end, the transfer head 40 may include one of an electrostatic chuck, an adhesive chuck, a vacuum chuck, and/or a porous vacuum chuck.

As shown in FIG. 7, the transfer member 21 includes a base layer 210 and a stamp layer 220 disposed on one surface of the base layer 210.

The base layer 210 may include, for example, glass and/or plastic. When the base layer 210 includes thin glass, the glass may be an ultra-thin glass. Alternatively, the base layer 210 may include at least one of, for example, polyethylene terephthalate (PET), polyurethane (PU), polyimide (PI), polycarbonate (PC), polyethylene (PE), polypropylene (PP), polysulfone (PSF), polymethylmethacrylate (PMMA), triacetylcellulose (TAC), cycloolefin polymer (COP), etc.

The stamp layer 220 is disposed on one surface of the base layer 210. The stamp layer 220 may be detachably attached or adhered to the light-emitting elements LE. The stamp layer 220 may be made of a material that is adhesive or detachable. Examples of adhesive materials may include, for example, an optical clear adhesive (OCA), a pressure sensitive adhesive (PSA), etc. Examples of detachable materials may include, for example, an acrylic, urethane, and/or silicone. The stamp layer 220 may have a thickness smaller than that of the base layer 210.

The protective film 30 may be attached to one surface of the transfer member 21, and the transfer head 40 may be adsorbed on the opposite surface of the transfer member 21. The protective film 30 is attached to one surface of the stamp layer 220 of the transfer member 21 to prevent contaminants from adhering to the stamp layer 220.

The protective film 30 may include, for example, glass and/or plastic. When the protective film 30 includes a thin glass, the glass may be an ultra-thin glass.

The protective film 30, the stamp layer 220, and the base layer 210 may be stacked on the support member Sta in this order. Subsequently, referring to FIG. 8, the protective film 30 attached to the surface of the stamp layer 220 may be removed for a process of attaching the light-emitting elements LE to the surface of the stamp layer 220 as will be described later.

After the transfer head 40 has picked up the transfer member 21, the protective film 30 is removed from the transfer member 21.

Referring back to FIG. 5, the transfer head 40 picks up the light-emitting elements LE from the donor substrate DS using the picked up transfer member 21 (step S120).

Referring to FIG. 9, the donor substrate DS on which a plurality of light-emitting elements LE is aligned and arranged is prepared. An adhesive material may be applied to the donor substrate DS. The donor substrate DS and the plurality of light-emitting elements LE may be adhered to each other by the adhesive material.

The transfer head 40 transfers the picked up transfer member 21 to the donor substrate DS, and adheres the light-emitting elements LE to the surface of the transfer member 21. Subsequently, the transfer head 40 is moved in the z-axis direction (e.g., the third direction DR3) to detach the light-emitting elements LE from the donor substrate DS.

Therefore, in order for the transfer head 40 to detach the light-emitting elements LE from the donor substrate DS through the transfer member 21, the adhesive force between the stamp layer 220 of the transfer member 21 and the light-emitting elements LE should be greater than the adhesive force between the donor substrate DS and the light-emitting elements LE. In addition, the transfer head 40 should apply a tensile force greater than the adhesive force between the donor substrate DS and the light-emitting elements LE in the z-axis direction (e.g., the third direction DR3).

As described above with reference to FIG. 4, the light-emitting elements LE may include the base substrate SPUB, the n-type semiconductor NSEM, the active layer MQW, the p-type semiconductor PSEM, the first contact electrode CTE1, and the second contact electrode CTE2. In addition, the light-emitting elements LE may further include the bonding electrodes 23. The bonding electrodes 23 may be melted by a laser or the like for bonding. Bonding of the bonding electrodes 23 will be described in detail with reference to FIG. 11.

Referring back to FIG. 5, the transfer head 40 aligns the transfer member 21 having the light-emitting elements LE attached thereto on the circuit board 10, and the transfer member 21 is detached from the transfer head 40 (step S130).

Referring to FIG. 10, the circuit board 10 may be a substrate SUB with the thin-film transistor layer TFTL formed thereon of FIG. 4.

A flux 24 having a suitable thickness (e.g., a predetermined thickness) may be applied onto the circuit board 10. The flux 24 may be a material that facilitates bonding between the circuit board 10 and the bonding electrodes 23 during a process of pressing and melting using a laser. The flux 24 may be oil soluble or water soluble and may include natural or synthetic resin. The flux 24 may be in liquid or gel form. Once the process of pressing and melting is completed, the flux 24 is removed.

In one or more embodiments, the flux 24 may be applied with a thickness smaller than that of the light-emitting elements LE. However, the thickness of the flux 24 may be equal to or greater than the height of the light-emitting elements LE (in the third direction DR3) at some locations due to the arrangement of the light-emitting elements LE, etc.

The transfer head 40 transfers the transfer member 21 having the light-emitting elements LE attached thereto to a desired location, and then releases the adsorption of the transfer member 21 to detach the transfer member 21 from the transfer head 40.

Referring again to FIG. 5, the light-emitting elements LE attached to the transfer members 21 are bonded onto the circuit board 10 (step S140).

Referring to FIG. 11, light-emitting elements LE to be bonded are disposed on the circuit board 10, and bonding electrodes 23 are disposed on one surface of the light-emitting elements LE in contact with the circuit board 10. The transfer member 21 is disposed on the opposite surface of each of the light-emitting elements LE, so that the circuit board 10, the light-emitting elements LE, and the transfer member 21 overlap part. A laser-transmitting member 8 may be disposed on the transfer member 21.

The laser-transmitting member 8 may be made of a material that transmits a laser LS. The laser-transmitting member 8 may be made of any beam-transmitting material.

The laser-transmitting member 8 may be made of, for example, one or more selected from the group of quartz, sapphire, fused silica glass, and/or diamond. The physical properties of the laser-transmitting member 8 made of quartz are different from the physical properties of the laser-transmitting member 8 made of sapphire. For example, when a laser LS at 980 nm is irradiated, the transmittance of the laser-transmitting member 8 made of quartz may be 85% to 99%, and the transmittance of the laser-transmitting member 8 made of sapphire may be 80% to 90%. In order to prevent damage to the laser-transmitting member 8 made of quartz and to improve the durability, a thin-film coating layer may be formed on the bottom surface of the laser-transmitting member 8 made of quartz. The thin-film coating layer formed on the bottom surface of the laser-transmitting member 8 may be made of a dielectric coating, a SiC coating, and/or a metallic material coating, which are typical optical coatings.

A pressing member 5 may be connected to the laser-transmitting member 8. The pressing member 5 may apply pressure in a particular direction. For example, the pressing member 5 may apply pressure in the third direction DR3. Accordingly, the laser-transmitting member 8 connected to the pressing member 5 may press the transfer member 21 in the third direction DR3.

As the laser LS is irradiated onto the bonding electrodes 23 while the transfer member 21 is pressed with the laser-transmitting member 8, the laser LS can pass through the laser-transmitting member 8 and the transfer member 21 to be irradiated onto the bonding electrodes 23. Accordingly, the laser LS can apply heat to the bonding electrodes 23 up to the melting temperature of the bonding electrodes 23, to bond the circuit board 10 to the bonding electrodes 23 by pressing and melting. Herein, the bonding by pressing and melting refers to that the bonding electrodes 23 are heated and melted by the irradiation of the laser LS so that the light-emitting elements LE are melted and mixed with the anode pad electrode APD and the cathode pad electrode CPD, and they are cooled and solidified after the laser supply is terminated. Because the light-emitting elements LE and the anode pad electrode APD and the cathode pad electrode CPD maintain conductivity even though they are cooled and solidified after they have been melted and mixed, the anode pad electrode APD and the cathode pad electrode CPD, and the light-emitting elements LE can be electrically and physically connected with each other.

In one or more embodiments, the operations of the transfer head 40, the pressing member 5, and the laser-transmitting member 8 may be controlled by a controller. For example, the controller may control the operation of the laser-transmitting member 8 using data input from a pressure sensor and a height sensor. The controller may receive data from the pressure sensor and control the pressing member 5 so that the pressure reaches the target value, and may also receive data from the height sensor and control the pressing member 5 and the laser-transmitting member 8 so that the height reaches the target value.

Although eutectic bonding is conducted, i.e., laser LS is radiated onto the bonding electrodes 23 disposed on one end of the light-emitting elements LE so that the electrodes are melted and bonded to the circuit board 10 in the example shown in FIG. 11, the present disclosure is not limited thereto. Any bonding technique well known in the art may be employed, such as soldering bonding carried out by melting a solder ball between the light-emitting elements LE and the circuit board 10 to bond between them, and anisotropic conductive film (ACF) bonding carried out by heating up an anisotropic conductive film between the light-emitting elements LE and the circuit board 10 to bond between them.

Referring back to FIG. 5, the transfer head 40 may remove the transfer member 21 from the circuit board 10 (step S150).

Referring to FIG. 12, the transfer head 40 is attached to the transfer member 21 disposed on the light-emitting elements LE bonded to the circuit board 10, and then the transfer member 21 is pulled in the z-axis direction (e.g., the third direction DR3) from the transfer head 40 with an attractive force (e.g., an adhesive force) greater than the adhesive force between the light-emitting elements LE and the transfer member 21. As a result, the transfer member 21 is detached from the light-emitting elements LE bonded to the circuit board 10. The adhesive force between the light-emitting elements LE and the circuit board 10 may be very strong (e.g., may be the strongest), the bonding force between the transfer member 21 and the transfer head 40 may be weaker than the adhesive force between the light-emitting elements LE and the circuit board 10, and the attaching force (e.g., an adhesive force) between the light-emitting elements LE and the transfer member 21 may be the weakest. Therefore, when force is applied in the z-axis direction (e.g., the third direction DR3) to the circuit board 10, the light-emitting elements LE, the transfer member 21, and the transfer head 40 overlapping one another in the z-axis direction (e.g., the third direction DR3), the light-emitting elements LE and the transfer member 21 may be detached from each other because they have the weakest adhesive force.

Subsequently, referring to FIG. 13, the flux 24 on the circuit board 10 to which the light-emitting elements LE are bonded is removed using a flux cleaner. Any flux cleaner well known in the art (e.g., a water-based flux cleaner) may be used. For example, flux cleaners such as CLEANTHROUGH® 750HS and CLEANTHROUGH® 750K available from Kao Corporation, or PINE ALPHA ST-100S available from Arakawa Chemical Industries, Ltd. may be used. CLEANTHROUGH® is a registered trademark on Kao Corporation, Tokyo, Japan. It should be understood, however, that the present disclosure is not limited thereto.

Cleaning conditions when cleaning the circuit board 10 are not particularly limited. For example, the circuit board 10 may be cleaned at a cleaning temperature of 30° C. to 50° C. for 1 to 5 minutes, preferably at 40° C. for 2 to 4 minutes.

Referring to FIG. 14, each of the light-emitting elements LE may be in contact with the anode pad electrode APD and the cathode pad electrode CPD of the circuit board 10 through the bonding electrode 23. As described above with reference to FIG. 4, the first contact electrode CTE1 of the light-emitting element LE may be in contact with the anode pad electrode APD of the circuit board 10, and the second contact electrode CTE2 of the light-emitting element LE may be in contact with the cathode pad electrode CPD.

Although flip-chip light-emitting elements are illustrated according to one or more embodiments of the present disclosure, the present disclosure is not limited thereto. Vertical light-emitting elements may be used in other embodiments.

As described above, according to one or more embodiments of the present disclosure, by using the transfer member that is detachable from the transfer head and is disposable, there is no need to worry about adhesion of contaminants, such as a flux, to the transfer member.

In addition, because the transfer member is removed after the bonding process, it is possible to avoid the flux applied onto the circuit board from being in direct contact with the laser-transmitting member, thereby preventing contamination of the laser-transmitting member.

FIG. 15 is a flowchart for illustrating a method of fabricating a display panel according to one or more embodiments of the present disclosure.

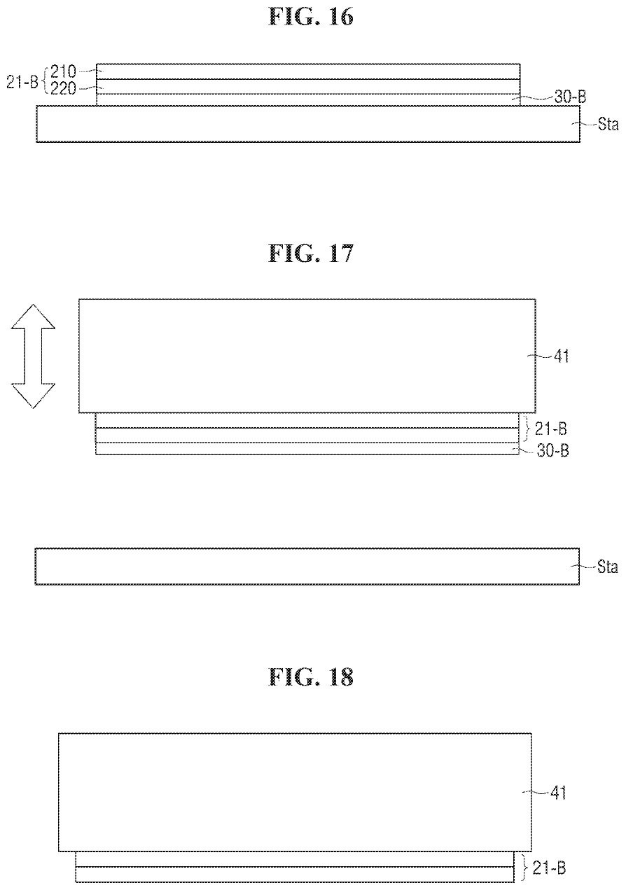

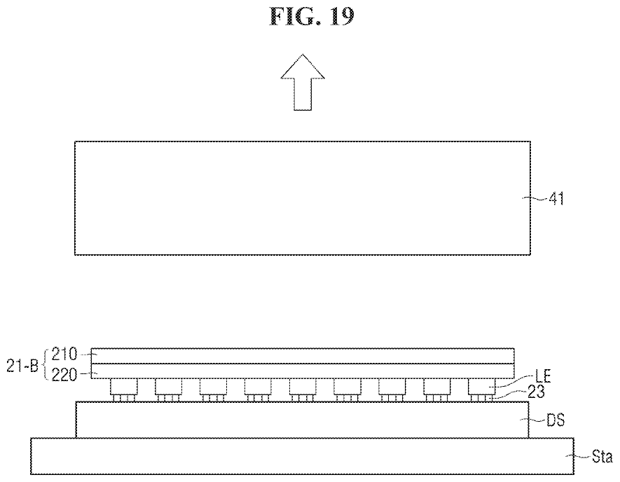

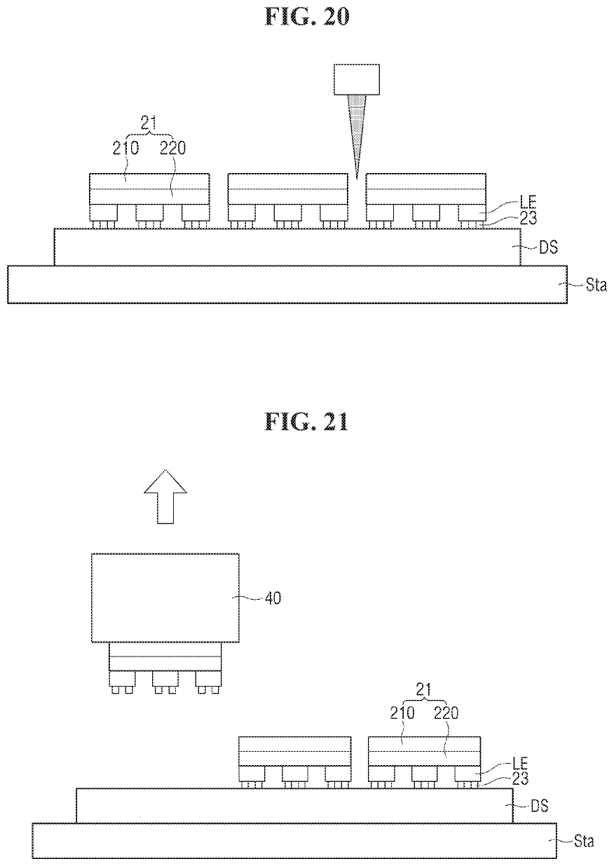

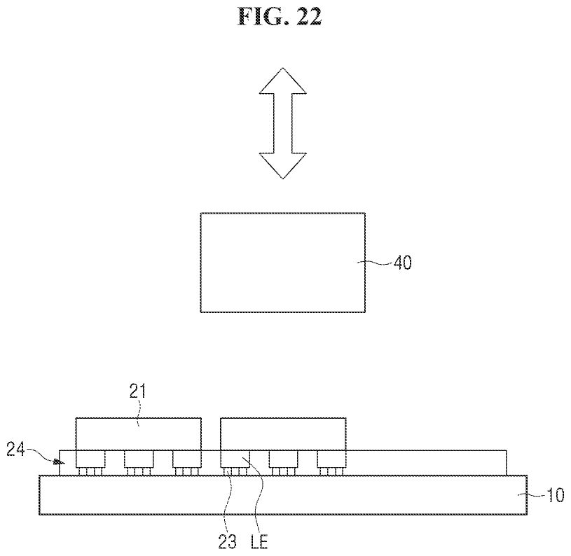

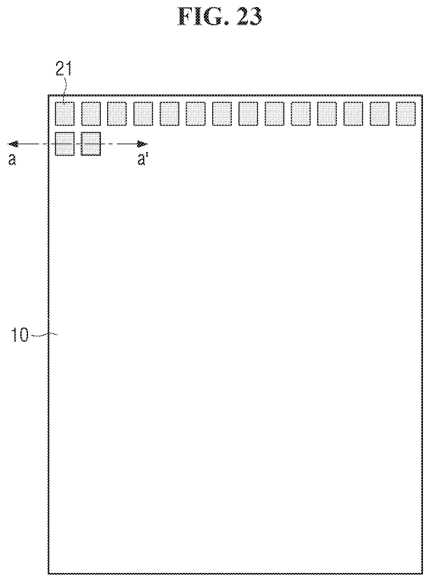

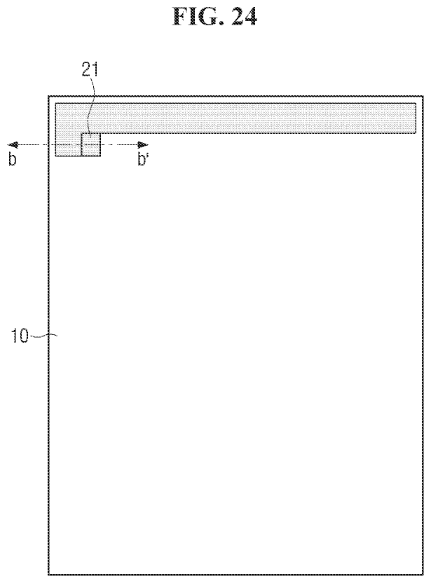

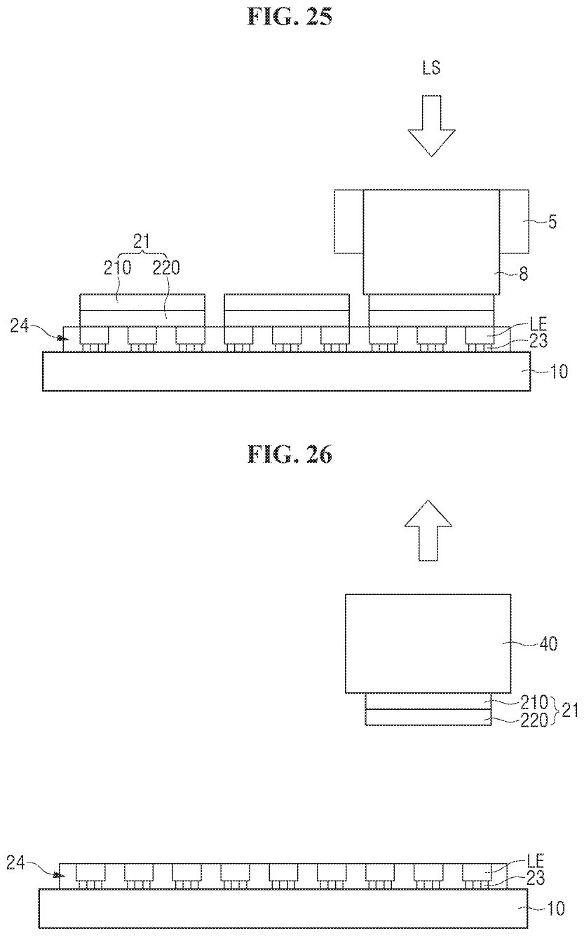

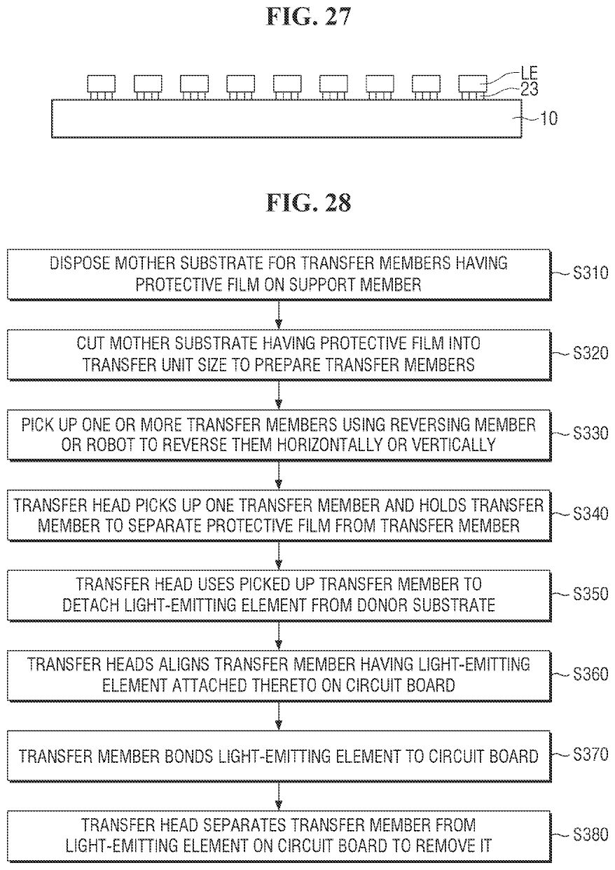

FIG. 16 is a cross-sectional view of a mother substrate for transfer members disposed on a support member. FIG. 17 is a view for illustrating picking up the mother substrate. FIG. 18 is a cross-sectional view showing the mother substrate after the protective film has been detached from it. FIG. 19 is a view for illustrating a process of disposing a mother substrate on light-emitting elements. FIG. 20 is a view showing a process of cutting the mother substrate into a transfer unit size. FIG. 21 is a view for illustrating picking up light-emitting elements attached on a donor substrate. FIGS. 22 to 23 are views for illustrating a method of transferring light-emitting elements onto a circuit board according to one or more embodiments. FIG. 24 is a view for illustrating a method of transferring light-emitting elements onto a circuit board according to one or more embodiments. FIG. 25 is a view for illustrating a method of bonding light-emitting elements onto a circuit board. FIG. 26 is a view for illustrating a method of separating a transfer member on a circuit board. FIG. 27 is a view for illustrating a method of cleaning a flux from a circuit board.

Hereinafter, a method of fabricating a display panel 100 using a transfer member 21 according to one or more embodiments will be described with reference to FIGS. 15 to 27.

Referring initially to FIG. 15, a first head 41 may pick up a mother substrate 21-B for transfer members 21 that has a protective film 30-B attached thereto and is disposed on a support member Sta (step S210).

More specifically, referring to FIG. 16, a mother substrate 21-B for transfer members 21 (see FIG. 20) to having a protective film 30-B attached thereto is disposed on a support member Sta.

The mother substrate 21-B for transfer members 21 includes a base layer 210 and a stamp layer 220.

The base layer 210 may include, for example, glass and/or plastic. When the base layer 210 includes thin glass, the glass may be ultra-thin glass. Alternatively, the base layer 210 may be made of one or more selected from the group of, for example, polyethylene terephthalate (PET), polyurethane (PU), polyimide (PI), polycarbonate (PC), polyethylene (PE), polypropylene (PP), polysulfone (PSF), polymethylmethacrylate (PMMA), triacetylcellulose (TAC), cycloolefin polymer (COP), and/or the like.

The stamp layer 220 is disposed on one surface of the base layer 210. The stamp layer 220 may be detachably attached or adhered to the light-emitting elements LE. The stamp layer 220 may be made of, but is not limited to, an adhesive material such as an optical clear adhesive (OCA) and/or a pressure sensitive adhesive (PSA). As another example, the stamp layer 220 may be made of a detachable material, and may include, for example, an acrylic, urethane, and/or silicone.

The stamp layer 220 has the protective film 30-B attached to one surface and the base layer 210 attached to the opposite surface.

The base layer 210 has the stamp layer 220 attached to one surface and the opposite surface thereof is exposed.

One surface of the protective film 30-B is attached to the stamp layer 220 while the opposite surface faces the support member Sta.

Referring to FIG. 17, a first head 41 picks up the mother substrate 21-B with the protective film 30-B disposed on the support member Sta.

The first head 41 may include one of an electrostatic chuck, an adhesive chuck, a vacuum chuck, and a porous vacuum chuck.

The first head 41 may adsorb the upper surface of the mother substrate 21-B by utilizing the adsorption ability of the chuck. Because the protective film 30-B, the stamp layer 220, and the base layer 210 are sequentially disposed on the support member Sta, the first head 41 may adsorb the upper surface of the base layer 210 to lift the mother substrate 21-B. The first head 41 may also lift the protective film 30-B attached to the lower surface of the mother substrate 21-B.

Referring back to FIG. 15, the first head 41 holds the mother substrate 21-B to separate the protective film 30-B from the mother substrate 21-B (step S220).

Referring to FIG. 18, the first head 41 lifts and holds the mother substrate 21-B to separate the protective film 30-B from the mother substrate 21-B for transfer members 21.

Referring back to FIG. 15, the first head 41 attaches the mother substrate 21-B to the light-emitting elements LE arranged on the donor substrate DS, and detaches the transfer members 21 from the first head 41 (step S230).

Referring to FIG. 19, a plurality of light-emitting elements LE may be aligned and disposed on the donor substrate DS. An adhesive material may be applied to the donor substrate DS. The donor substrate DS and the plurality of light-emitting elements LE may be adhered to each other.

The first head 41 may place the picked up mother substrate 21-B on the plurality of light-emitting elements LE on the donor substrate DS. In doing so, the stamp layer 220 of the mother substrate 21-B may be attached to the upper surfaces of the light-emitting elements LE. The first head 41 has a sufficient width to cover the surface of the mother substrate 21-B.

Referring to FIGS. 15 and 20, the mother substrate 21-B is singulated (e.g., cut) on the donor substrate DS into a transfer unit size, to prepare a plurality of transfer members 21 (step S240).

The cutting may be carried out by techniques well known in the art such as mechanical cutting and laser cutting. The transfer unit size refers to the size transferred to the circuit board 10 at one time.

Referring back to FIGS. 15, 21 and 22, a transfer head 40 aligns the transfer member 21 having the light-emitting elements LE attached thereto on the circuit board 10, and the transfer member 21 is detached from the transfer head 40 (step S250).

An adhesive material may be applied to the donor substrate DS. The donor substrate DS and the plurality of light-emitting elements LE may be adhered to each other by the adhesive material.

Referring to FIG. 21, the transfer head 40 transfers the picked up transfer member 21 to the donor substrate DS, and adheres the light-emitting elements LE to a surface of the transfer member 21. Subsequently, the transfer head 40 is moved in the z-axis direction (e.g., the third direction DR3) to detach the light-emitting elements LE from the donor substrate DS. The transfer head 40 may have a sufficient width to cover the surface of the transfer member 21 and may be narrower than of the first head 41. The transfer head 40 may be similar (e.g., substantially identical) to the transfer head 40 according to the above-described embodiment.

In order for the transfer head 40 to detach the light-emitting elements LE from the donor substrate DS through the transfer member 21, the adhesive force between the stamp layer 220 of the transfer member 21 and the light-emitting elements LE should be greater than the adhesive force between the donor substrate DS and the light-emitting elements LE. In addition, the transfer head 40 should apply a tensile force greater than the adhesive force between the donor substrate DS and the light-emitting elements LE in the z-axis direction (e.g., the third direction DR3).

Referring back to FIG. 22, the transfer head 40 aligns the light-emitting elements LE attached to the transfer member 21 on the circuit board 10, and the transfer head 40 is detached from the transfer member 21.

For example, the transfer head 40 transfers the transfer member 21 having the light-emitting elements LE attached thereto to a desired location, and then releases the adsorption of the transfer member 21 to detach the transfer member 21 from the transfer head 40.

The circuit board 10 may be a substrate SUB with the thin-film transistor layer TFTL formed thereon of FIG. 4. The light-emitting elements LE may further include the bonding electrodes 23 on a surface.

A flux 24 having a desired thickness (e.g., a predetermined thickness) may be applied to the circuit board 10. The flux 24 may be a material that facilitates bonding between the circuit board 10 and the bonding electrodes 23 during a process of pressing and melting using a laser. The flux 24 may be oil soluble or water soluble and may include natural or synthetic resin. The flux 24 may be in liquid or gel form. Once the process of pressing and melting is completed, the flux 24 is removed.

In one or more embodiments, the flux 24 may be applied with a thickness smaller than that of the light-emitting elements LE. However, the thickness of the flux 24 may be equal to or greater than the height of the light-emitting elements LE (e.g., in the third direction DR3) at some locations due to the arrangement of the light-emitting elements LE, etc.

The transfer head 40 transfers the transfer member 21 having the light-emitting elements LE attached thereto to a desired location, and then releases the adsorption of the transfer member 21 to detach the transfer member 21 from the transfer head 40.

Referring to FIGS. 22 and 23, transfer members 21 disposed on the circuit board 10 may be spaced from one another. The circuit board 10 may be singulated (e.g., cut) into the size of each transfer member 21. Each singulated unit of the circuit board 10 may be used for a small display device such as a smart watch.

Referring to a modification shown in FIG. 24, transfer members 21 disposed on a circuit board 10 may be arranged without spacing so that seams between the transfer members 21 are not recognized. A plurality of circuit boards 10 may be disposed to implement a tiled display device.

As can be seen from FIGS. 22 to 24, a method of fabricating a display panel according to one or more embodiments may be applied to a large-sized display device as well as a small-sized display device.

Referring to FIG. 25, the light-emitting elements LE attached to the transfer members 21 are bonded onto the circuit board 10 (step S260). The bonding technique is substantially similar (e.g., substantially identical) to that described above with reference to FIGS. 5 and 11; and, therefore, the redundant descriptions will be omitted.

Referring to FIGS. 15 and 26, the transfer head 40 removes the transfer member 21 from the circuit board 10 (step S270).

The transfer head 40 is attached to the transfer member 21 disposed on the light-emitting elements LE bonded to the circuit board 10, and then the transfer member 21 is pulled in the z-axis direction (e.g., the third direction DR3) from the transfer head 40 with an attractive force (e.g., an adhesive force) greater than the adhesive force between the light-emitting elements LE and the transfer member 21. As a result, the transfer member 21 is detached from the light-emitting elements LE bonded to the circuit board 10. The adhesive force between the light-emitting elements LE and the circuit board 10 may be very strong (e.g., may be the strongest), the bonding force between the transfer member 21 and the transfer head 40 may be weaker than the bonding force between the light-emitting elements LE and the circuit board 10, and the attaching force between the light-emitting elements LE and the transfer member 21 may be the weakest. Therefore, when a force is applied in the z-axis direction (e.g., the third direction DR3) to the circuit board 10, the light-emitting elements LE, the transfer member 21 and the transfer head 40 overlapping one another in the z-axis direction (e.g., the third direction DR3), the light-emitting elements LE and the transfer member 21 can be detached from each other because they have the weakest adhesive force.

Subsequently, referring to FIG. 27, the flux 24 on the circuit board 10 to which the light-emitting elements LE are bonded is removed using a flux cleaner. The removal of the flux 24 has been described above with reference to FIG. 13; and, therefore, the redundant descriptions will be omitted.

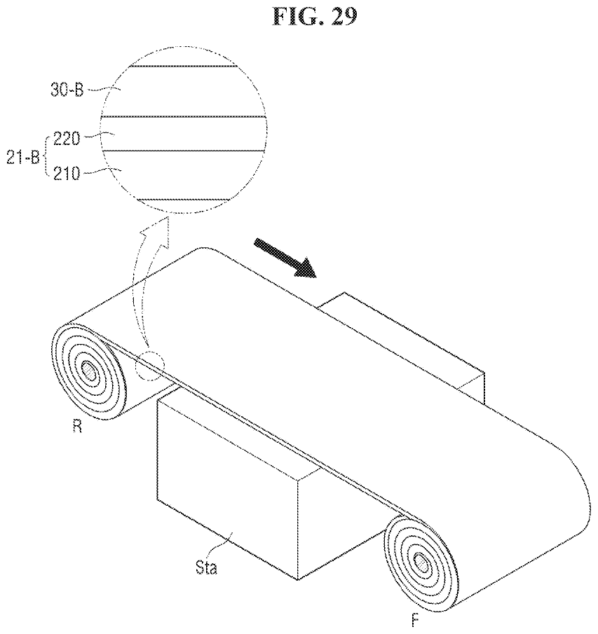

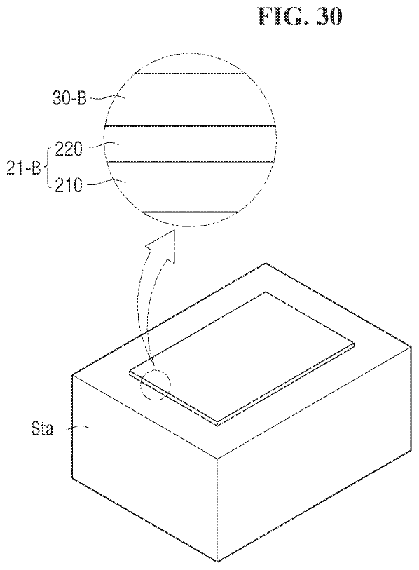

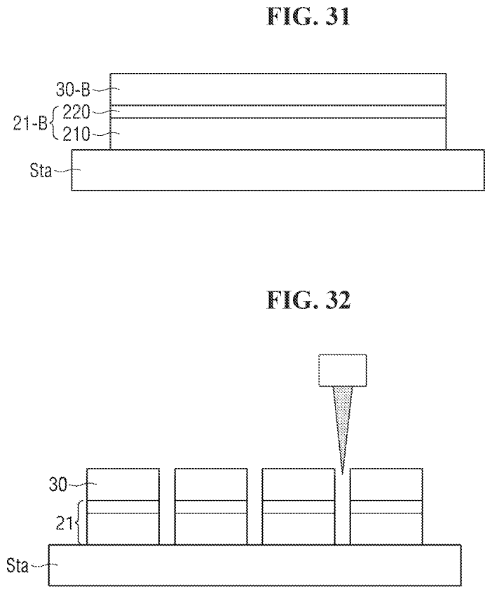

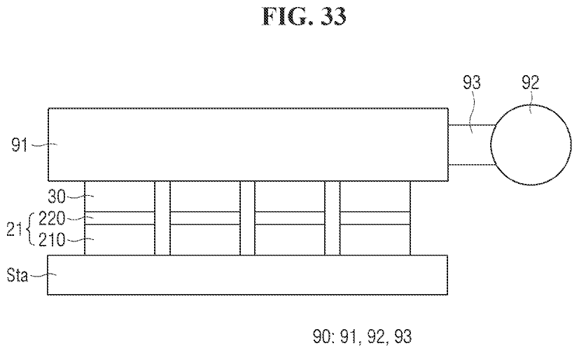

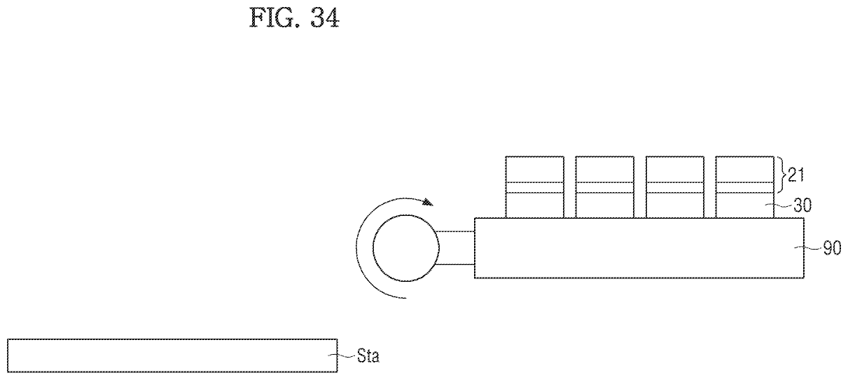

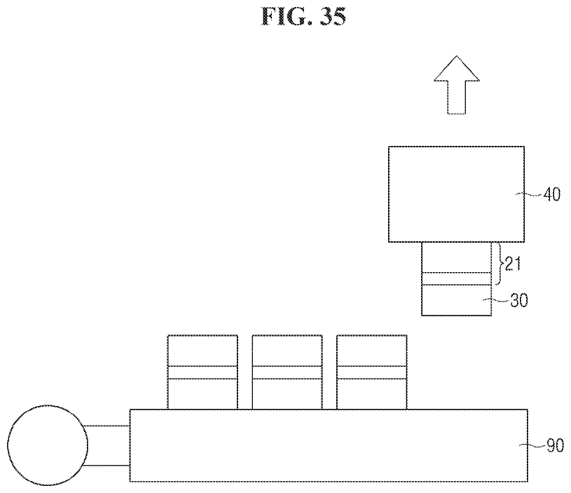

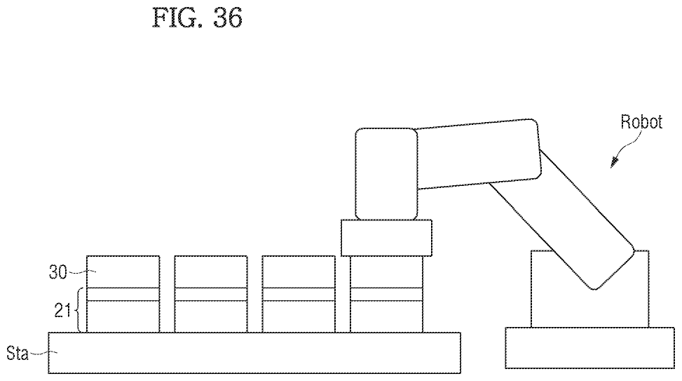

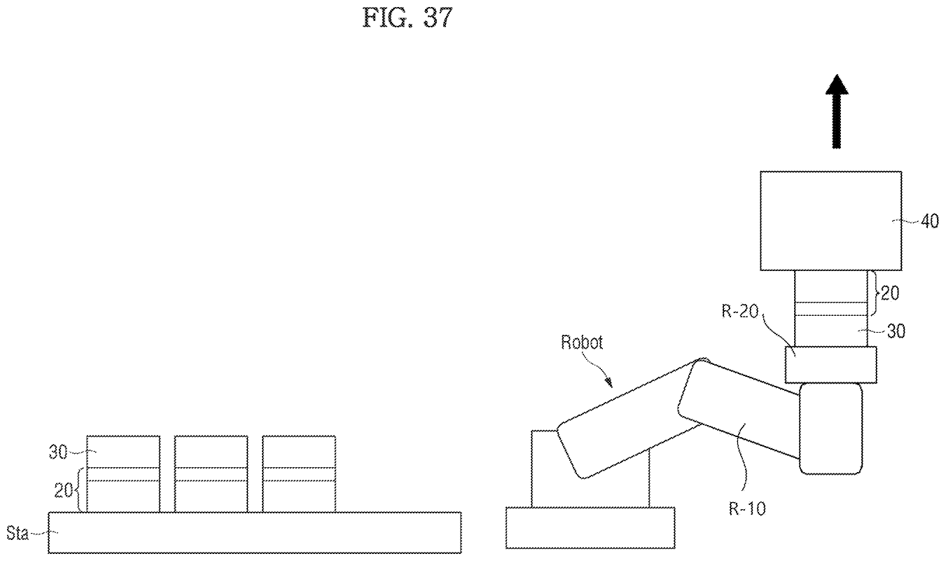

FIG. 28 is a flowchart for illustrating a method of fabricating a display panel according to one or more embodiments of the present disclosure. FIG. 29 is a perspective view for illustrating a mother substrate for transfer members of a roll-to-roll type. FIG. 30 is a perspective view for illustrating a mother substrate for transfer members of a sheet type. FIG. 31 is a cross-sectional view of a transfer member disposed upside down on a support member. FIG. 32 is a view showing a process of cutting the mother substrate into a transfer unit size. FIGS. 33 and 34 are views for illustrating reversing transfer members by a reversing member. FIG. 35 is a view for illustrating picking up a transfer member. FIGS. 36 and 37 are views for illustrating reversing transfer members by a reversing member.

Hereinafter, a method of fabricating a display panel 100 using a transfer member 21 according to one or more embodiments will be described with reference to FIGS. 28 to 37.

Referring to FIG. 28, a mother substrate 21-B for transfer members 21 having a protective film 30-B attached thereto is disposed on a support member Sta (step S310).

As shown in FIG. 29, a mother substrate 21-B may be of a roll-to-roll type wound in the form of a roll. When the mother substrate 21-B is of a roll-to-roll type, it may be cut into a desired width for use. The mother substrate 21-B includes a base layer 210 and a stamp layer 220 disposed on one surface of the base layer 210, and may further include a protective film 30-B.

In addition, as shown in FIG. 30, the mother substrate 21-B may be of a sheet type.

Referring to FIG. 31, the mother substrate 21-B including the protective film 30-B includes a base layer 210, a stamp layer 220, and the protective film 30-B stacked on one another from the support member Sta in this order. The base layer 210 has one side surface facing the support member Sta and the opposite side surface facing the stamp layer 220. The stamp layer 220 has one side surface facing the base layer 210 and the opposite side surface facing the protective film 30-B. The stamp layer 220 is made of a material that is adhesive or detachable.

Referring back to FIGS. 28 and 32, the mother substrate 21-B including the protective film 30-B is singulated (e.g., cut) into the transfer unit size on the support member Sta to prepare a plurality of transfer members 21 (step S320).

The cutting may be carried out by techniques well known in the art such as mechanical cutting and laser cutting. The transfer unit size refers to the size transferred to the circuit board 10 at one time.

Referring to FIG. 28, the plurality of transfer members 21 is picked up by a reversing member 90 or robot to reverse them horizontally or vertically (step S330).

For example, referring to FIG. 33, the reversing member 90 may adsorb one surface of the protective film 30 attached to the plurality of transfer members 21 arranged and aligned on the support member Sta. The reversing member 90 may include a stage 91, a rotation shaft 92, and a connector 93 connecting the stage 91 with the rotation shaft 92. The stage 91 may be rotated by 180 degrees around the rotation axis of the rotation shaft 92. The stage 91 may include one of an electrostatic chuck, an adhesive chuck, a vacuum chuck, and a porous vacuum chuck.

Referring to FIGS. 33 and 34, the reversing member 90 may adsorb the surface of the protective film 30 and rotate by 180 degrees, to reverse the transfer member 21 having the protective film 30 attached thereto vertically or horizontally. The protective film 30, the stamp layer 220, and the base layer 210 of the transfer member 21 may be disposed in this order from the reversing member 90.

Referring to FIGS. 28 and 35, the transfer head 40 picks up one of the plurality of transfer members 21. The transfer head 40 may hold the transfer member 21 to remove the protective film 30 from the transfer member 21 (step S340).

Referring to FIG. 28, the transfer head 40 attaches the light-emitting elements LE disposed on the donor substrate DS to the picked up transfer member 21, and detaches the light-emitting elements LE from the donor substrate DS (step S350). A detailed description thereof is substantially similar (e.g., substantially identical) to that given above with reference to FIG. 9; and, therefore, the redundant description will be omitted.

Subsequently, the transfer head 40 aligns the transfer member 21 having the light-emitting elements LE attached thereto on the circuit board 10, and the transfer member 21 is detached from the transfer head 40 (step S360). A detailed description thereof is substantially similar (e.g., substantially identical) to that given above with reference to FIG. 10; and, therefore, the redundant description will be omitted.

The light-emitting elements LE attached to the transfer member 21 are bonded onto the circuit board 10 (step S370). A detailed description thereof is substantially similar (e.g., substantially identical) to that given above with reference to FIG. 11; and, therefore, the redundant description will be omitted.

The transfer head 40 separates and removes the transfer member 21 from the light-emitting elements LE on the circuit board 10 (step S380). A detailed description thereof is substantially similar (e.g., substantially identical) to that given above with reference to FIG. 12; and, therefore, the redundant description will be omitted.

FIGS. 36 and 37 are views for illustrating a method of reversing a transfer member according to one or more embodiments.

In the following description, the method of reversing the stacking order of the base layer 210, the stamp layer 220, and the protective film 30 sequentially stacked on the support member Sta by an articulated robot Robot having a plurality of joints has been described.

Referring to FIGS. 36 and 37, instead of the reversing member 90, an articulated robot Robot having a plurality of joints reverses the stacking order of the base layer 210, the stamp layer 220 and the protective film 30 sequentially stacked on the support member Sta in reverse order.

More specifically, the articulated robot Robot includes a body R-10 having a rotary joint, and a chuck R-20 located at the tip of the body R-10 and used for bonding the transfer member 21 (or 20) accommodated on the support member Sta. The body R-10 and the chuck R-20 of the articulated robot Robot are well known in the art and thus will not be described herein. The chuck R-20 may be one of an electrostatic chuck, an adhesive chuck, a vacuum chuck, and/or a porous vacuum chuck.

The articulated robot Robot may adsorb a surface of the protective film 30 using the chuck R-20 to rotate it by 180 degrees, to reverse the transfer member 21 having the protective film 30 attached thereto vertically or horizontally. As a result, the protective film 30 of the transfer member 21 is located at the bottom, and the transfer member 21, that is, the stamp layer 220 and the base layer 210 may be placed on the protective film 30 in this order.

The articulated robot Robot may be reversed to the position of the transfer head 40 and transfer the transfer member 21 having the protective film 30 attached thereto. In one or more embodiments, the transfer member 21 may move to the articulated robot Robot to adsorb the transfer member 21 having the protective film 30 attached thereto. Subsequently, the same process as in FIGS. 34 to 36 may be performed.

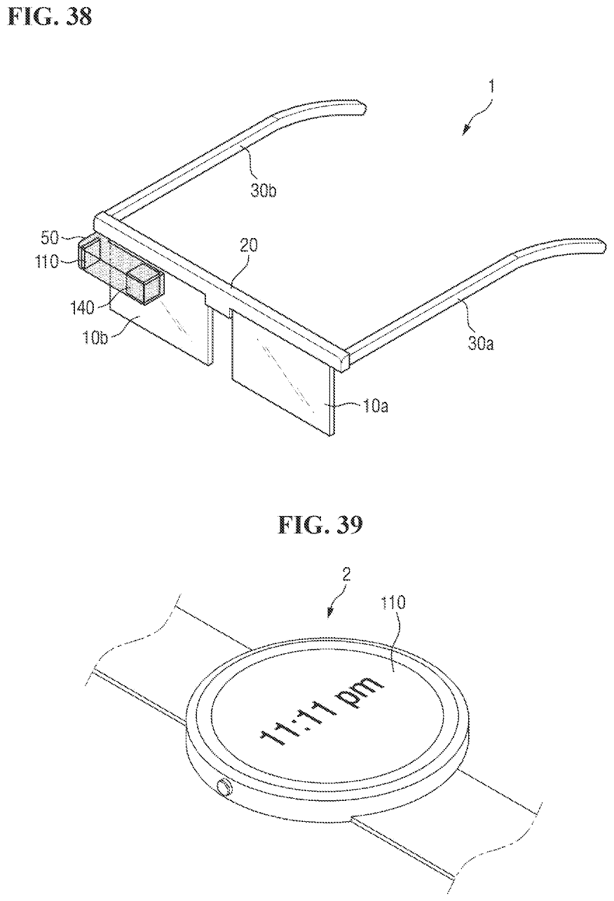

According to the above-described embodiment, the mother substrate 20-B is cut while the protective film 30 faces the upper side unlike the embodiment of FIG. 15, so that it is possible to address the problem of defective transfer process in which contaminants remain on the base layer 210. FIG. 38 is a view illustrating a virtual reality device including a display device according to one or more embodiments. In FIG. 38, a virtual reality device 1 to which a display device 110 according to one or more embodiments is applied is shown.

Referring to FIG. 38, the virtual reality device 1 according to one or more embodiments may be a glasses-type device. The virtual reality device 1 according to one or more embodiments may include a display device 110, a left-eye lens 10a, a right-eye lens 10b, a support frame 20, glasses frame legs 30a and 30b, a reflection member 140, and a display device accommodating portion 50.

Although FIG. 38 illustrates the virtual reality device 1 that includes glasses frame legs 30a and 30b, the virtual reality device 1 according to one or more embodiments may be applied to a head mounted display including a head mounting band, which may be mounted on a head, instead of the glasses frame legs 30a and 30b. That is, the virtual reality device 1 is not limited to that shown in FIG. 38 and is applicable to various electronic devices in various forms.

The display device accommodating portion 50 may include a display device 110 and a reflection member 140. The image displayed on the display device 110 may be reflected by the reflection member 140 and provided to a user's right eye through the right-eye lens 10b. In this manner, the user may view a virtual reality image displayed on the display device 110 through the right eye.

Although FIG. 38 illustrates that the display device accommodating portion 50 is disposed at a right end of the support frame 20, the present disclosure is not limited thereto. For example, the display device accommodating portion 50 may be disposed at a left end of the support frame 20, and in such an embodiment, the image displayed on the display device 110 may be reflected by the reflection member 140 and provided to the user's left eye through the left-eye lens 10a. In this manner, the user may view the virtual reality image displayed on the display device 110 through the left eye. In another embodiment, the display device accommodating portion 50 may be disposed at both the left end and the right end of the support frame 20, and in this manner, the user may view the virtual reality image displayed on the display device 110 through both the left eye and the right eye.

FIG. 39 is a view illustrating a smart device including a display device according to one or more embodiments.

Referring to FIG. 39, a display device 110 according to one or more embodiments may be applied to a smart watch 2, which is a type of smart device.

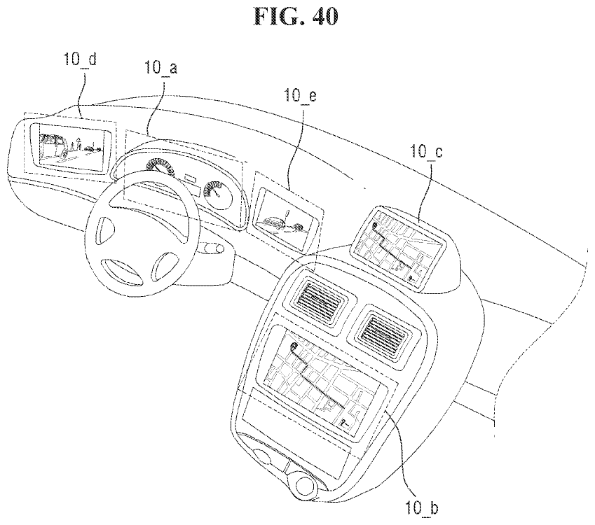

FIG. 40 is a view illustrating a vehicle dashboard and a center fascia including display devices according to one or more embodiments. A vehicle to which display devices 10_a, 10_b, 10_c, 10_d and 10_e according to one or more embodiments are applied is shown in FIG. 40.

Referring to FIG. 40, the display devices 10_a, 10_b, and 10_c according to one or more embodiments may be applied to a dashboard of the vehicle, applied to a center fascia of the vehicle, or applied to a center information display (CID) disposed on the dashboard of the vehicle. In one or more embodiments, the display devices 10_a, 10_b, and 10_c may be used as a display device. In addition, the display devices 10_d and 10_e according to one or more embodiments may be applied to a room mirror display that replaces a side mirror of the vehicle.

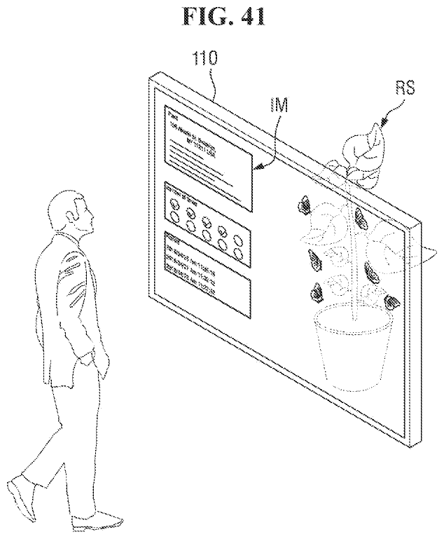

FIG. 41 is a view illustrating a transparent display device including a display device according to one or more embodiments.

Referring to FIG. 41, a display device 110 according to one or more embodiments may be applied to the transparent display device. The transparent display device may display an image IM and, at the same time, may transmit light. Therefore, a user located in front of a front surface of the transparent display device may not only view the image IM displayed on the display device 110 but may also view an object RS or background located on a rear surface of the transparent display device. When the display device 110 is applied to the transparent display device, the substrate SUB of the display device 110, shown in, for example, FIG. 4, may include a light transmitting portion configured to transmit light or may be formed of a light transmissive material.

However, aspects and features of the present disclosure are not limited to those set forth herein. The above and other aspects and features of the present disclosure will become more apparent to one of ordinary skill in the art to which the disclosure pertains by referencing the claims, with equivalents thereof to be included within the scope thereof.

What is claimed is:

1. A method of fabricating a display panel, the method comprising:
picking up, by a transfer head, a transfer member located on a support member;
detaching a light-emitting element from a donor substrate by attaching the transfer member picked up by the transfer head to the light-emitting element on the donor substrate to lift the light-emitting element;
aligning, by the transfer head, the light-emitting element attached to the transfer member on a circuit board, and detaching the transfer member from the transfer head;
bonding the light-emitting element attached to the transfer member onto the circuit board; and
separating, by the transfer head, the transfer member from the light-emitting element bonded to the circuit board to remove the transfer member.

2. The method of claim 1, wherein the transfer member comprises a base layer and a stamp layer on a surface of the base layer, and wherein the stamp layer comprises a material that is adhesive or detachable.

3. The method of claim 2, wherein a protective film is located between the support member and the transfer member, and wherein the protective film is attached to a surface of the stamp layer and the base layer is attached to an opposite surface of the stamp layer.

4. The method of claim 3, wherein the picking up the transfer member comprises: picking up, by the transfer head, the transfer member by adsorbing the base layer, and holding the transfer member to separate the protective film from the transfer member.

5. The method of claim 1, wherein the circuit board comprises a flux applied onto one surface.

6. The method of claim 5, further comprising: after the separating the transfer member from the light-emitting element bonded to the circuit board to remove the transfer member, removing the flux from the circuit board by a flux cleaner.

7. The method of claim 1, wherein the bonding the light-emitting element onto the circuit board comprises at least one of: an eutectic bonding by irradiating laser onto a bonding electrode located at one end of the light-emitting element to melt the bonding electrode and bond the light-emitting element to the circuit board; a soldering bonding by melting and bonding a solder ball between the light-emitting element and the circuit board; and an anisotropic conductive film (ACF) bonding by heating and bonding an anisotropic conductive film between the light-emitting element and the circuit board.

8. The method of claim 1, wherein the support member supports a plurality of transfer members, and wherein each of the plurality of transfer members has a same transfer unit size as a transfer area on the circuit board that is transferred at one time.

9. The method of claim 1, wherein the light-emitting element comprises an n-type semiconductor, an active layer, a p-type semiconductor, a first contact electrode, and a second contact electrode.

10. A method of fabricating a display panel, the method comprising:
picking up, by a first head, a mother substrate for transfer members that is on a support member and has a protective film attached to the mother substrate;
holding, by the first head, the mother substrate to separate the protective film from the mother substrate;
attaching, by the first head, the mother substrate onto light-emitting elements arranged and aligned on a donor substrate, and detaching the mother substrate from the first head;
cutting the mother substrate into a transfer unit size on the donor substrate to prepare the transfer members;
arranging, by a second head, the transfer member having the light-emitting elements attached thereto on a circuit board, and detaching the transfer member from the second head;
bonding the light-emitting elements attached to the transfer member onto the circuit board; and
separating, by the second head, the transfer member from the light-emitting elements bonded to the circuit board to remove the transfer member.

11. The method of claim 10, wherein the mother substrate comprises a base layer and a stamp layer on a surface of the base layer, and wherein the stamp layer comprises a material that is adhesive or detachable.

12. The method of claim 10, wherein a size of the second head is smaller than or equal to the transfer unit size and smaller than a size of the first head.

13. A method of fabricating a display panel, the method comprising:
placing a mother substrate for transfer members having a protective film on a support member;
cutting the mother substrate having the protective film into a transfer unit size on the support member to prepare the transfer members;
picking up the transfer members using a reversing member or a robot and reversing the transfer members vertically and horizontally;
picking up, by a transfer head, a transfer member of the transfer members to hold the transfer member to separate the protective film from the transfer member;
attaching, by the transfer head, light-emitting elements on a donor substrate to the picked up transfer member and detaching the light-emitting elements from the donor substrate;
aligning, by the transfer head, the transfer member having the light-emitting elements attached thereto on a circuit board, and detaching the transfer member from the transfer head;
bonding the light-emitting elements attached to the transfer member on the circuit board; and
separating, by the transfer head, the transfer member from the light-emitting elements on the circuit board to remove the transfer member.

14. The method of claim 13, wherein the placing the mother substrate comprises disposing the mother substrate of a roll-to-roll type or a sheet type.
